(19) United States
(12) Patent Application Publication
(10) Pub. No.: US 2013/0102156 A1
(43) Pub. Date: Apr. 25, 2013

(54) COMPONENTS OF PLASMA PROCESSING CHAMBERS HAVING TEXTURED PLASMA RESISTANT COATINGS

(71) Applicant: Lam Research Corporation, Fremont, CA (US)

(72) Inventors: Tom Stevenson, Morgan Hill, CA (US); Hong Shih, Walnut, CA (US); Robert G. O'Neill, Fremont, CA (US); Tae Won Kim, Dublin, CA (US); Raphael Casaes, Santa Clara, CA (US); Yan Fang, Fremont, CA (US)

(73) Assignee: Lam Research Corporation, Fremont, CA (US)

(21) Appl. No.: 13/625,489

(22) Filed: Sep. 24, 2012

Related U.S. Application Data
(60) Provisional application No. 61/549,895, filed on Oct. 21, 2011.

(51) Int. Cl. B05B 1/00; B32B 3/02; H01L 21/3065; B32B 3/30; B05D 3/12; C23C 16/44

(52) U.S. Cl. 438/710; 427/331; 427/248.1; 427/289; 428/155; 428/66.6; 239/589; 257/E21.218

(57) ABSTRACT

A component of a plasma processing chamber includes a three dimensional body having a highly dense plasma resistant coating thereon wherein a plasma exposed surface of the coating has a texture which inhibits particle generation from film buildup on the plasma exposed surface. The component can be a window of an inductively coupled plasma reactor wherein the window includes a textured yttria coating. The texture can be provided by contacting the plasma exposed surface with a polishing pad having a grit size effective to provide intersecting scratches with a depth of 1 to 2 microns.

### CROSS REFERENCE TO RELATED APPLICATION

This application claims priority under 35 U.S.C. §119(e) to U.S. Provisional Application No. 61/549,895, filed on Oct. 21, 2011, the entire content of which is incorporated herein by reference thereto.

### BACKGROUND

The invention relates to components of a plasma processing chamber in which semiconductor substrates are processed.

Referring now to FIG. 1, a simplified diagram of inductively coupled plasma processing system components is shown. Generally, the plasma chamber (chamber) 202 is comprised of a bottom chamber section 250 forming a sidewall of the chamber, an upper chamber section 244 also forming a sidewall of the chamber, and a cover 252. An appropriate set of gases is flowed into chamber 202 from gas distribution system 222. These plasma processing gases may be subsequently ionized to form a plasma 220, in order to process (e.g., etch or deposition) exposed areas of substrate 224, such as a semiconductor substrate or a glass pane, positioned with edge ring 215 on an electrostatic chuck (chuck) 216. Gas distribution system 222 is commonly comprised of compressed gas cylinders (not shown) containing plasma processing gases (e.g., C₄F₈, C₄F₆, CHF₃, CH₂F₃, CF₄, HBr, CH₃F, C₂F₄, N₂, O₂, Ar, Xe, He, H₂, NH₃, SF₆, BCl₃, Cl₂, etc.).

Induction coil 231 is separated from the plasma by a dielectric window 204 forming the upper wall of the chamber, and generally induces a time-varying electric current in the plasma processing gases to create plasma 220. The window both protects induction coil from plasma 220, and allows the generated RF field 208 to generate an inductive current 211 within the plasma processing chamber. Further coupled to induction coil 231 is matching network 232 that may be further coupled to RF generator 234. Matching network 232 attempts to match the impedance of RF generator 234, which typically operates at about 13.56 MHz and about 50 ohms, to that of the plasma 220. Additionally, a second RF energy source 238 may also be coupled through matching network 236 to the substrate 224 in order to create a bias with the plasma, and direct the plasma away from structures within the plasma processing system and toward the substrate. Gases and byproducts are removed from the chamber by a pump 220.

Generally, some type of cooling system 240 is coupled to chuck 216 in order to achieve thermal equilibrium once the plasma is ignited. The cooling system itself is usually comprised of a chiller that pumps a coolant through cavities within the chuck, and helium gas pumped between the chuck and the substrate. In addition to removing the generated heat, the helium gas also allows the cooling system to rapidly control heat dissipation. That is, increasing helium pressure increases the heat transfer rate. Most plasma processing systems are also controlled by sophisticated computers comprising operating software programs. In a typical operating environment, manufacturing process parameters (e.g., voltage, gas flow mix, gas flow rate, pressure, etc.) are generally configured for a particular plasma processing system and a specific recipe.

In addition, a heating and cooling apparatus 246 may operate to control the temperature of the upper chamber section 244 of the plasma processing apparatus 202 such that the inner surface of the upper chamber section 244, which is exposed to the plasma during operation, is maintained at a controlled temperature. The heating and cooling apparatus 246 is formed by several different layers of material to provide both heating and cooling operations.

The upper chamber section itself is commonly constructed from plasma resistant materials that either will ground or are transparent to the generated RF field within the plasma processing system (e.g., coated or uncoated aluminum, ceramic, etc.).

For example, the upper chamber section can be a machined piece of aluminum which can be removed for cleaning or replacement thereof. The inner surface of the upper chamber section is preferably coated with a plasma resistant material such as a thermally sprayed yttria coating. Cleaning is problematic in that the ceramic coatings of this type are easily damaged and due to the sensitive processing of some plasma processes, it is sometimes preferred to replace the upper chamber section rather than remove it for cleaning.

In addition, correctly reseating the upper chamber section after maintenance is often difficult, since it must properly be aligned with the bottom chamber section such that a set of gaskets properly seal around the upper chamber section. A slight misalignment will preclude a proper mounting arrangement.

The volume of material in the upper chamber section also tends to add a substantial thermal mass to the plasma processing system. Thermal mass refers to materials have the capacity to store thermal energy for extended periods. In general, plasma processes tend to very sensitive to temperature variation. For example, a temperature variation outside the established process window can directly affect the etch rate or the deposition rate of polymeric films, such as poly-fluorocarbon, on the substrate surface. Temperature repeatability between substrates is often desired, since many plasma processing recipes may also require temperature variation to be on the order of a few tenths of ° C. Because of this, the upper chamber section is often heated or cooled in order to substantially maintain the plasma process within established parameters.

As the plasma is ignited, the substrate absorbs thermal energy, which is subsequently measured and then removed through the cooling system. Likewise, the upper chamber section can be thermally controlled. However, plasma processing may require temperature changes during multi-step processing and it may be necessary to heat the upper chamber section to temperatures above 100° C., e.g. 120, 130, 140, 150 or 160° C. or any temperature therebetween whereas the prior upper chamber sections were run at much lower temperatures on the order of 60° C. The higher temperatures can cause undesirable increases in temperature of adjacent components such as the bottom chamber section. For example, if it is desired to run the upper chamber section and overlying dielectric window at temperatures on the order of 130 to 150° C. and the bottom chamber section at ambient temperatures of about 30° C., heat from the much hotter upper chamber section can flow into the bottom chamber section and raise its temperature sufficiently to affect the plasma processing conditions seen by the semiconductor substrate. Thus, heat flow variations originating from the upper chamber section may cause the substrate temperature to vary outside narrow recipe parameters.

In view of the foregoing, replaceable upper chamber parts having desired features which cooperate to optimize plasma processing in a plasma processing system would be of interest.

### SUMMARY

According to one embodiment, a component of a plasma processing chamber includes a three dimensional body having a highly dense plasma resistant coating thereon wherein a plasma exposed surface of the coating has a texture which inhibits particle generation from film buildup on the plasma exposed surface. The coating preferably has a thickness of 10 to 60 microns deposited by aerosol deposition. The coating is preferably a yttria coating having a porosity below 1% by volume and yttria content of at least 99.9% by weight Y₂O₃. The texture preferably comprises intersecting scratches having a depth of 1 to 2 microns with smooth areas having roughness (Ra) below 0.01 micron located between the intersecting scratches. The roughness (Ra) of the intersecting scratches preferably is 0.3 to 0.5 microns, more preferably about 0.4 microns.

### BRIEF DESCRIPTION OF THE DRAWING FIGURES

FIG. 1 shows a simplified diagram of a plasma processing system;

FIG. 2 shows a perspective view of an exemplary plasma chamber which can include a window as described herein.

FIGS. 3A-I show details of a ceramic window in accordance with one embodiment.

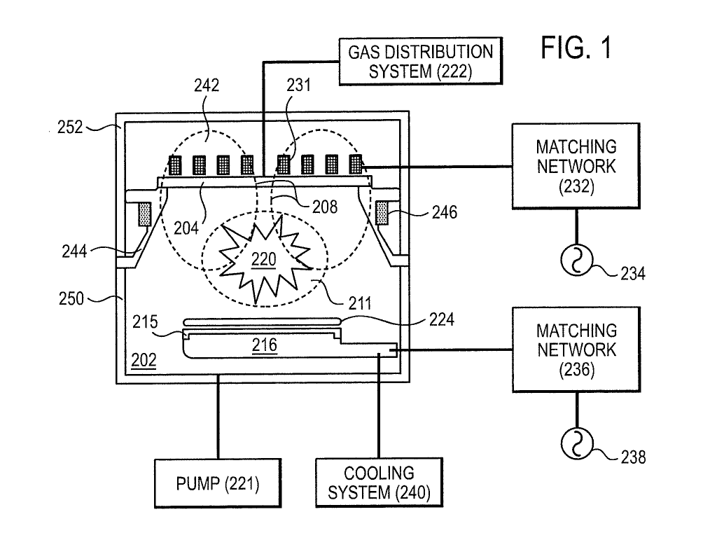

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention. As used herein, the term “about” should be construed to include values up to 10% above or below the values recited.

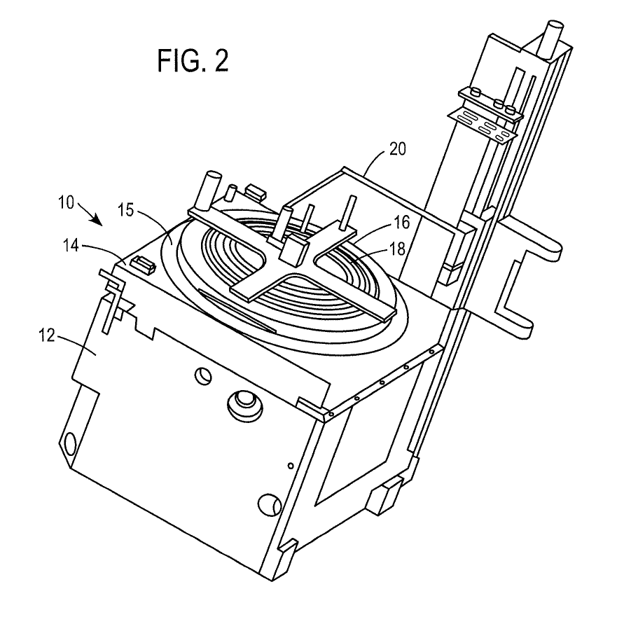

Described herein are components of a plasma chamber such as that illustrated in FIG. 2. The components include a ceramic window and gas injector which mounts in an opening in the window.

The plasma system shown in FIG. 2 includes a chamber 10 which includes a lower chamber 12 and an upper chamber 14. The upper chamber 14 includes a top chamber interface 15 which supports a dielectric window 16. An RF coil 18 overlies the window and supplies RF power for energizing process gas into a plasma state inside the chamber. A top gas injector is mounted in the center of the window for delivering process gas from gas supply line 20.

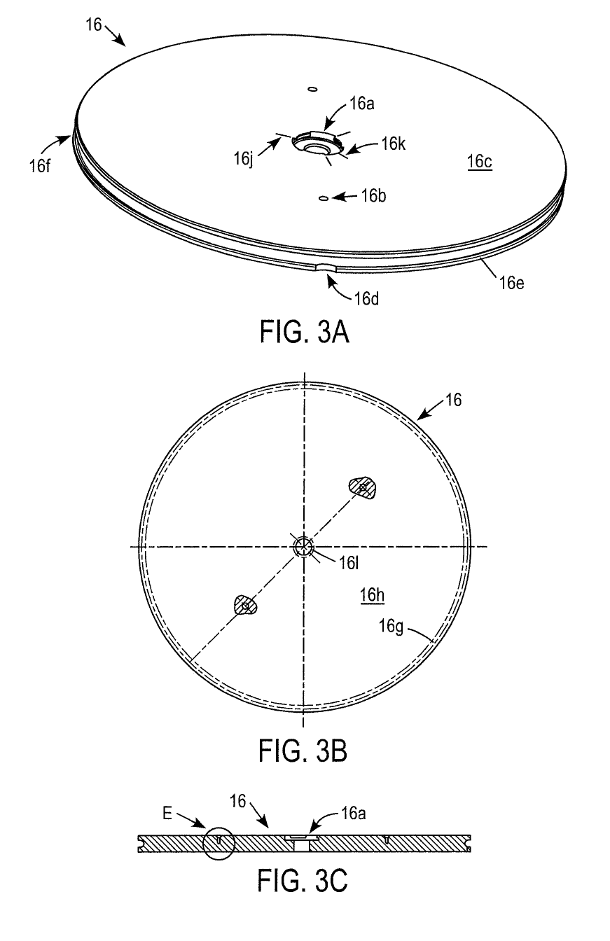

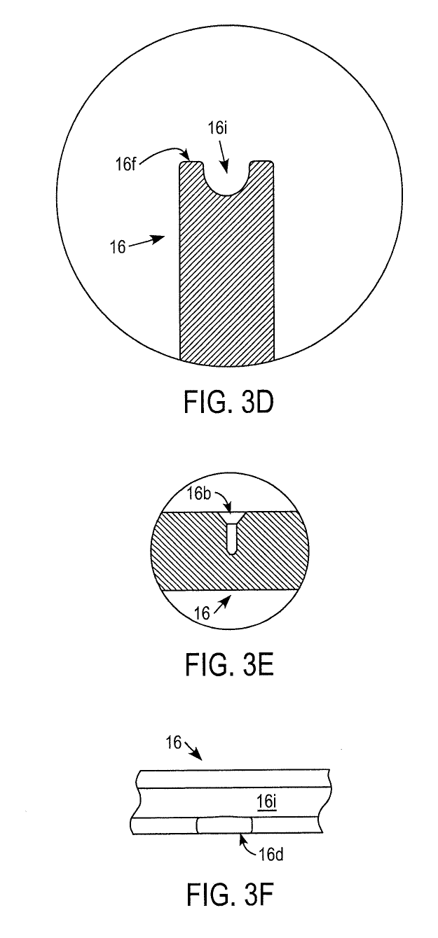

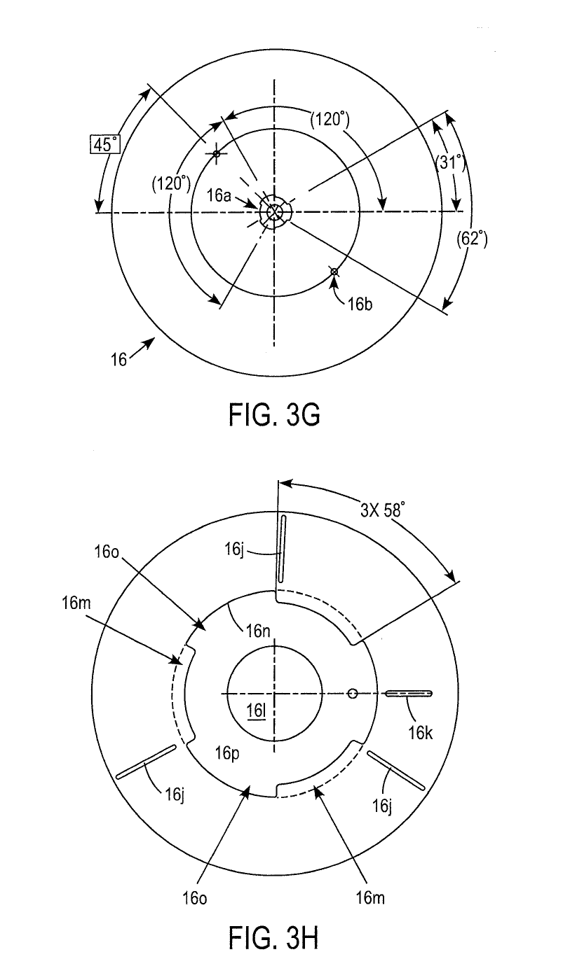

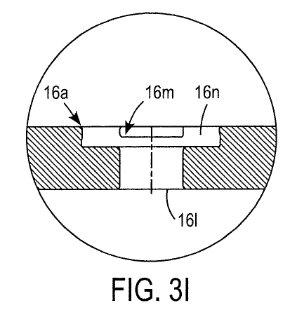

FIG. 3A shows details of a window 16 which includes a central opening 16a for receipt of a gas injector, blind holes 16b in upper surface 16c for receipt of temperature sensors, and a clocking feature 16d in a bottom flange 16e of the outer side surface 16f. FIG. 3B is a bottom view of the window shown in FIG. 3A illustrating a vacuum sealing surface 16g which is outward of a plasma exposed surface comprising a textured ceramic coating 16h such as yttrium oxide. FIG. 3C is a cross section of the window and FIG. 3D is a cross section of the outer periphery of the window wherein a rounded recess 16i extends into the sidewall 16f. FIG. 3E shows further details and dimensions of one of the blind bores 16b in Detail E in FIG. 3C. FIG. 3F shows details and dimensions of the clocking feature 16d which is a recess having a radius of 0.625 inch extending into the side of the window at a single location and edges of the recess form an angle of 90° with the center of the radius. FIG. 3G shows details and dimensions of the window. FIG. 3H shows a top view of an enlarged view of the bayonet opening 16a and FIG. 3I shows a cross section of the bayonet opening 16a.

As shown in FIG. 3A, the window 16 includes three radial laser engraved marks 16j located 120° apart and a single shorter mark 16k about 32° from one of the longer marks 16j. These marks are used for visual alignment and to gauge tightness when the gas injector is installed in the bayonet opening 16a.

FIG. 3B is a bottom view of the window 16 wherein an annular vacuum sealing surface 16g surrounds the textured coating 16h. The window preferably has a diameter of about 22 inches and the vacuum seal 16k is preferably an annular zone about 0.5 to 1 inch, preferably about 0.75 inch, in width. The window is preferably flat across the bottom of the window and the vacuum sealing surface is formed directly on the yttria coating. The vacuum sealing surface is on a smooth section of the coating and the coating is textured inward of the vacuum seal.

FIG. 3C is a cross section of the window 16 wherein the rounded recess 16i extends into the side surface 16f and the bayonet opening 16a includes a small diameter bore 16l and a wider recess 16m having three flanges 16n and three slots 16o which form the bayonet opening 16a. The bottom of the recess 16m is a vacuum sealing surface 16p which engages a vacuum seal on a portion of the gas injector.

FIG. 3D shows details of the annular groove 16i which extends about 0.4 inch into the side wall 16f and a rounded bottom of the groove 16i has a radius of about 0.25 inch with the center of the groove 16i located about 0.6 inch from the upper surface of the window 16. The groove 16i has parallel walls extending from the rounded bottom to the side surface 16f and edges of the groove 16i and outer edges of the window are rounded with a radius of about 0.05 inch. The window 16 preferably has a uniform thickness of about 1 inch and is preferably made of high purity alumina.

FIG. 3E shows details of one of the blind holes 16b where a lower portion of the blind hole 16b has a diameter of about 0.13 inch and an upper portion of the blind hole 16b is tapered with a diameter of about 0.4 inch at the entrance of the blind hole 16b.

FIG. 3F shows details of the clocking feature 16d which extends into the lower surface of the window 16 though the bottom flange 16e forming part of the groove 16i. The clocking feature has a radius of about 0.6 inch and the center of curvature of the clocking feature 16d is located about 11.4 inches from the center of the bayonet opening 16a.

FIG. 3G is a top view of the window showing the location of the blind holes 16b in relation to the bayonet opening 16a. The blind holes 16b are 180° apart and located about 5.6 inches from the center of the bayonet opening 16a. While two blind holes are shown, the window may have a single blind hole located about 5.6 inches from the center of the bayonet opening 16a.

FIG. 3H shows details of the bayonet opening 16a wherein three slots 16o are located between three flanges 16n. Each of the flanges 16n extends about 58° and an inner edge of each flange 16n is about 1 inch from the center of the bayonet opening 16a. The slots 16o are formed by segments of the cylindrical recess 16m which has a radius of about 1.15 inch from the center of the bayonet opening 16a. As shown in FIG. 3I, the cylindrical recess 16m extends under the flanges 16n and the space between the vacuum sealing surface 16p and the underside of the flanges 16n enables mounting of the gas injector by inserting the gas injector axially in the bore 16l and rotating a twist-and-lock support for the gas injector engages outward projections on the twist-and-lock support beneath the flanges 16n to removably mount the gas injector in the window 16.

In accordance with a preferred embodiment, the window is a ceramic disk with a bore in the middle that interfaces with a ceramic gas injector. The entire bottom of the window preferably has a highly dense ceramic coating which is textured inwardly of a vacuum seal formed at the outermost portion of the coating. An O-ring seal can be provided at the interface between the window and the top chamber interface. The ceramic disk is about 1 inch thick and is made from a low loss tangent high purity ceramic material such as alumina and is coated on the bottom recessed surface with yttrium oxide for plasma resistance. The disk has two blind bores on the top surface that accept a thermal couple (TC) and a Resistance Temperature Detector (RTD). The location and depth of the TC and RTD are selected to achieve desired process temperature monitoring and avoid damage to the window. The bottom of the TC and RTD holes have a spherical radius to reduce the stress concentration of the hole. However, the window can have a single blind bore for receipt of a temperature sensor.

The contact area between the top chamber interface and the window determines the amount of heat transferred between these two components.

During plasma processing, the middle of the window is hot, and it is desirable for the contact area to conduct heat into the edge of the window to help make the temperature of the OD close to that of the middle. At idle (when plasma is not generated in the chamber), the middle of the window is cold, and it is desirable for the contact area to not conduct any heat into the window and to match the temperature of the middle of the window.

Particles are a common problem within the semiconductor industry that result in issues with device manufacturing, either through prevention of deposition or removal (etching) of layers in the device. As devices become increasingly smaller, the manufacture of these devices becomes increasingly sensitive to smaller and smaller particles.

An additional concern is that as the device sizes become increasingly smaller, there is an increased sensitivity to chamber chemistry changes over time. This can be managed by coating the inside of the chamber between each wafer being processed to “reset” the chamber chemistry. This is commonly called a “pre-coat” which can be a coating of silicon, oxygen and other elements such as hydrogen.

Metal contamination has been a considerable problem in the industry, especially while manufacturing layers close to the gate where doping effects lead to changes in device electrical performance and reliability. This has led to the development of many plasma resistant materials or coatings. One common coating is plasma sprayed yttria. While the technology has improved considerably over the years, plasma sprayed yttria has fundamentally high roughness and high porosity (˜5%). The process of plasma spraying produces a loosely bound agglomeration of yttria particles on the surface of the substrate which are an artifact of the multiple molten particles impinging on the substrate during processing. These loosely bound particles have some level of probability in falling off during the processing of a wafer, creating issues during the manufacturing process. There has been much research into alternate spray coating techniques and surface conditioning to produce a denser and smoother coating, as well as cleaning processes, to mitigate these loose particles although they are largely mitigations. In parallel to these activities, there has been much research conducted into the fabrication of thin films that do not suffer from the same porosity and particle generating issues, eliminating the source of particles all together. This can be done by processes such as CVD, PVD and Aerosol Deposition.

As discussed above, plasma spray coating produces an inherently rough surface and roughness values of 200 to 300 microinch Ra are not uncommon. While it is possible to reduce this by processes such as grinding and polishing, these processes cannot provide a surface that does not generate particles due to 1) the damage induced in the surface from the process and 2) the inherent porosity and associated weak bonding in the bulk material. Roughened surfaces do have the advantage of being able to distribute surface stresses in accumulated films from the wafer processes. This is due to the internal stresses in the film, be they compressive or tensile, which occur in the plane of the film. This stress is proportional to both the thickness and the total area of the film. On rough surfaces, these films cannot build significant levels of stress to a point where the deposition looses it's adherence to the plasma coating and flaking into the process chamber. This is due to the sudden changes in direction at a micro level on the surface. While this provides a significant advantage to a rough surface, it also has some undesirable side effects.

Due to the high surface area, the surface changes in chemistry slowly over time as more of the process gas is absorbed from the plasma, changing the etch rate over time. The solution to this is a smooth surface which cannot be achieved with the current plasma coating technology as discussed above without causing particle generation by other mechanisms.

Aerosol Deposition has been developed over the past 15 years to provide a film deposition technique which provides a manufacturing method for fabricating ceramic coatings of adequate thickness to fully encapsulate, while still remaining cost effect. The process typically requires a polishing step to eliminate loosely bonded particles on the surface, exposing the highly dense coating. This coating has recently been demonstrated to provide significant particle improvements over spray coating although it was found to shed particles of “pre-coat” after only a short period as the surface chemistry changed and the adhesive force dropped or accumulation became too thick and film stress lead to delamination.

It was hypothesized that the particle issue described above could be resolved by roughening the surface of the coating. Several processes were compared although what proved to be successful was by creating a textured surface in the form of a pattern of intersecting scratches using successively finer diamond pads on the surface. Initial attempts with sand blasting were unsuccessful as the impingement of particles on the surface resulted in subsurface damage which created loosely bonded particles on the surface. However, by creating a randomized scratch pattern, small local areas or plateaus were created on a micro-topological level that prevent deposited film stress building to a critical level where they delaminated from the coating and created particles.

Common roughening techniques take a rough surface and successively develop a smoother and smoother surface until the desired target roughness is established. The disadvantage of this type of process is that it is extremely challenging to create a repeatable surface finish. Another concern, specifically with brittle materials, is the elimination of damage to the surface. This damage is produced by the abrasive removal of material that creates cracks that propagate into the surface. This creates loosely bound particles in the surface that can result in particles in the process chamber. If the process starts with a smooth, polished surface, there is no damage in the starting surface. The slow roughening process creates striations in the material, while enough to remove material, it is not enough to induce damage in the surface, eliminating the risk of particle generation through damage.

A preferred surface treatment to create a scratch pattern comprises hand polishing the plasma exposed surface of the coating with a 180 diamond grit polishing pad for 4 minutes, then hand polishing the surface with a 220 diamond grit polishing for 4 minutes and then hand polishing the surface with a 280 diamond grit polishing pad. By polishing the surface with a circular motion, a scratch pattern of intersecting scratches can be obtained. This texture has been found to provide a reduction in particle contamination of wafers processed in a chamber incorporating a component with the textured coating.

The textured coating can be provided on the plasma exposed surface of the window or other components such as the gas injector. The gas injector is mounted with its distal end flush or below the bottom surface of the window to deliver process gas into the chamber. An induction coil (not shown) above the window energizes the process gas into a plasma state for processing the substrate. For example, an etch gas can be supplied by the injector for plasma etching the substrate.

The gas injector can include one or more gas outlets, an annular flange which sits on the bottom wall of the cylindrical recess is vacuum sealed to the window with an O-ring which fits in a groove on the bottom of the annular flange. An RF shield surrounds the gas injector and a faceplate surrounds the RF shield. The faceplate is a two piece part which is bolted together around the RF shield and the faceplate includes protrusions (lugs) to engage the bayonet opening in the window.

Having disclosed exemplary embodiments and the best mode, modifications and variations may be made to the disclosed embodiments while remaining within the subject and spirit of the invention as defined by the following claims.

We claim:

1. A component of a plasma processing chamber, comprising:
a three dimensional body having a highly dense plasma resistant coating thereon wherein a plasma exposed surface of the coating has a texture of interconnected scratches which inhibits particle generation from film buildup on the plasma exposed surface during processing of a semiconductor substrate in the plasma processing chamber.

2. The component of claim 1, wherein the coating is a yttria coating having a porosity below 1% by volume and yttria content of at least 99.9% by weight Y₂O₃.

3. The component of claim 1 wherein the coating is produced by aerosol deposition.

4. The component of claim 1, wherein the texture comprises intersecting scratches having depth of 1 to 2 microns.

5. The component of claim 1, wherein the coating has a thickness of 10 to 60 microns.

6. The component of claim 1, wherein the plasma exposed surface of the coating has a roughness (Ra) of 0.3 to 0.5 microns.

7. The component of claim 1, wherein the texture comprises smooth areas having roughness (Ra) below 0.01 micron and intersecting scratches having a depth of 1 to 2 microns.

8. The component of claim 1, wherein the component is a dielectric window having a diameter of at least 300 mm and a bayonet opening in the center thereof in which a gas injector can be mounted.

9. The component of claim 1, wherein the component is a cylindrical dielectric gas injector having gas outlets in the plasma exposed surface.

10. The component of claim 8, wherein the window has a continuous groove in an outer side wall thereof, the groove having a depth of about 0.4 inch and a width of about 0.5 inch, the groove having a rounded bottom with a radius of about 0.25 inch and parallel side walls, the bayonet comprising a cylindrical recess having a diameter of about 2.4 inches with three flanges extending radially inward from an upper end of the cylindrical recess, the three flanges separated by three slots extending about 62° and an inner surface of the flanges having a diameter of about 2 inches, the bayonet opening further including a vacuum sealing surface extending inward from a lower edge of the cylindrical recess and a bore having a diameter of about 1 inch extending through the vacuum sealing surface to the plasma exposed surface of the window.

11. The component of claim 10, wherein the window has an outer diameter of about 20 inches and a blind bore in an upper surface thereof located about 5 inches from the center of the window or the window has a diameter of about 22 inches and two blind bores 180° apart located about 5 inches from the center of the window.

12. A method of manufacturing the component of claim 1, comprising depositing the coating on the body such that an outer surface of the coating has a surface roughness (Ra) below 0.01 micron and forming the intersecting scratches on the outer surface.

13. The method of claim 12, wherein the depositing comprises aerosol deposition.

14. The method of claim 12, wherein the forming comprises contacting the outer surface with a polishing pad.

15. The method of claim 12, wherein the polishing pad is a 180 grit diamond polishing pad.

16. The method of claim 12, wherein the polishing pad is a 220 grit diamond polishing pad.

17. The method of claim 12, wherein the polishing pad is a 280 grit diamond polishing pad.

18. The method of claim 12, wherein the forming comprises hand rubbing the outer surface with a 180 grit diamond polishing pad for 1 to 10 minutes, then hand rubbing the outer surface with a 220 grit diamond polishing pad for 1 to 10 minutes, then hand rubbing the outer surface with a 280 grit diamond polishing pad for 1 to 10 minutes.

19. The method of claim 12, wherein the coating is 99.99% by weight pure Y₂O₃.

20. A method of plasma etching a semiconductor substrate in a plasma chamber incorporating the component wherein the component is a dielectric Window of an inductively coupled plasma chamber, the method comprising supplying an etch gas to the chamber, energizing the etch gas into a plasma state by transmitting RF energy through the window, and etching the semiconductor substrate.
